(19) United States
(12) Patent Application Publication
(10) Pub. No.: US 2019/0265538 A1
(43) Pub. Date: Aug. 29, 2019

(54) LIQUID CRYSTAL DISPLAY PANEL, METHOD FOR FABRICATING THE SAME AND DISPLAY DEVICE

(71) Applicants: BOE Technology Group Co., Ltd., Beijing (CN); HEFEI BOE DISPLAY TECHNOLOGY CO., LTD., Hefei (CN)

(72) Inventors: Ji ZHANG, Beijing (CN); Tao WANG, Beijing (CN); Guanyong ZHANG, Beijing (CN); Jincheng GAO, Beijing (CN); Guanbao HUI, Beijing (CN)

(21) Appl. No.: 16/158,842

(22) Filed: Oct. 12, 2018

(30) Foreign Application Priority Data
Feb. 26, 2018 (CN) 201810159393.9

(51) Int. Cl. G02F 1/1333; G02F 1/1335; H01L 27/12

(52) U.S. Cl. CPC G02F 1/133305; G02F 1/133514; G02F 2202/022; G02F 2202/16; G02F 2203/01; H01L 27/1214

(57) ABSTRACT

The disclosure discloses a liquid crystal display panel, a method for fabricating the same and a display device, where the liquid crystal display panel includes an array substrate and an opposite substrate arranged opposed to the array substrate, wherein a transparent flexible conductive film is arranged on a side of the opposite substrate facing away from the array substrate.

### CROSS-REFERENCE TO RELATED APPLICATION

This Application claims priority to Chinese Patent Application No. 201810159393.9, filed on Feb. 26, 2018, the content of which is incorporated by reference in the entirety.

### TECHNICAL FIELD

This disclosure relates to the field of semiconductor technologies and particularly to a liquid crystal display panel, a method for fabricating the same and a display device.

### DESCRIPTION OF THE RELATED ART

A Thin Film Transistor Liquid Crystal Display (TFT-LCD) panel is a commonly-used flat panel in the related art, for example, the TFT-LCD panel is widely applied in modern digital information devices due to its advantages of small volume, low power consumption, no radiation, high resolution and the like.

In a production process of the TFT-LCD panel, due to the factors of equipment and staffs, a static electricity cannot be avoided completely, and an accumulation of the static electricity may affect liquid crystals in the TFT-LCD panel, thus causing a disorder of images.

Further, in the related art, display surfaces of liquid crystal display panels are mostly flat surfaces and have a viewing angle problem. That is to say, when people views a liquid crystal display panel from a side, a viewed image of the liquid crystal display does not have an original color, and even worse, only a color of all white or all black can be viewed by the people. While a curved liquid crystal display panel can prevent an interference of a reflected light source and maintain a balanced and consistent viewing angle, therefore the color contrast is more extremely perfect and the image approximates reality. But the curved liquid crystal display panel in the related art has a problem of poor electrostatic shielding performance.

### SUMMARY

Embodiments of the disclosure provide a liquid crystal display panel, a method for fabricating the same and a display device.

In one aspect, the embodiments of the disclosure provide a liquid crystal display panel, which includes an array substrate and an opposite substrate arranged opposed to the array substrate, wherein a transparent flexible conductive film is arranged on a side of the opposite substrate facing away from the array substrate.

In some embodiments, the transparent flexible conductive film is an organic polymer conductive film.

In some embodiments, the opposite substrate includes an organic flexible base substrate; the organic polymer conductive film is arranged on a side of the organic flexible base substrate facing away from the array substrate.

In some embodiments, a material of the organic polymer conductive film is poly (3, 4-ethylene dioxythiophene): poly (styrene sulfonate), doped polyaniline or polypyrrole.

In some embodiments, a thickness of the transparent flexible conductive film is 10˜100 nm.

In some embodiments, the opposite substrate is a color filter substrate and a color filter layer is arranged on a side of the color filter substrate facing the array substrate.

In some embodiments, the liquid crystal display panel further includes a color filter layer and the color filter layer is arranged on the array substrate.

In some embodiments, the liquid crystal display panel is a curved liquid crystal display panel.

In another aspect, the embodiments of the disclosure provide a display device including a liquid crystal display panel, wherein the liquid crystal display panel includes an array substrate and an opposite substrate arranged opposed to the array substrate, wherein a transparent flexible conductive film is arranged on a side of the opposite substrate facing away from the array substrate.

In some embodiments, the transparent flexible conductive film is an organic polymer conductive film.

In some embodiments, the opposite substrate includes an organic flexible base substrate; the organic polymer conductive film is arranged on a side of the organic flexible base substrate facing away from the array substrate.

In some embodiments, a material of the organic polymer conductive film is poly (3, 4-ethylene dioxythiophene): poly (styrene sulfonate), doped polyaniline or polypyrrole.

In some embodiments, a thickness of the transparent flexible conductive film is 10˜100 nm.

In still another aspect, the embodiments of the disclosure provide a method for fabricating a liquid crystal display panel, including: forming a transparent flexible conductive film on an opposite substrate.

In some embodiments, forming the transparent flexible conductive film on the opposite substrate includes: forming the transparent flexible conductive film on the opposite substrate via a solution coating method or a spraying method.

In some embodiments, forming the transparent flexible conductive film on the opposite substrate via the spraying method includes: coating micro-droplets on the opposite substrate via an ultrasonic method or an electrostatic atomization method, and drying the opposite substrate.

In some embodiments, before forming the transparent flexible conductive film on the opposite substrate via the solution coating method or the spraying method, the method further includes: performing an atmospheric plasma process on the opposite substrate.

In some embodiments, forming the transparent flexible conductive film on the opposite substrate includes: forming the transparent flexible conductive film on the opposite substrate via a gaseous polymerization method.

In some embodiments, forming the transparent flexible conductive film on the opposite substrate via the gaseous polymerization method includes: forming a poly (3, 4-ethylene dioxythiophene): poly (styrene sulfonate) film on the opposite substrate via the gaseous polymerization method.

In some embodiments, forming the poly (3, 4-ethylene dioxythiophene): poly (styrene sulfonate) film on the opposite substrate via the gaseous polymerization method includes: coating an n-butyl alcohol dispersed with a ferric trichloride hexahydrate and a pyridine on the opposite substrate, and drying the opposite substrate at a first preset temperature for a first preset length of time; polymerizing a 3,4-ethylene dioxythiophene on the opposite substrate via a gaseous polymerization device; cleaning the opposite substrate with an ethyl alcohol, and annealing the opposite substrate at a second preset temperature for a second preset length of time.

### BRIEF DESCRIPTION OF THE DRAWINGS

In order to make the technical solutions according to the embodiments of the disclosure more apparent, the drawings to which a description of the embodiments refers will be briefly introduced below, and apparently the drawings to be described below are merely illustrative of some of the embodiments of the disclosure, and those ordinarily skilled in the art can derive from these drawings other drawings without any inventive effort.

FIG. 1 is a schematic structural diagram of a liquid crystal display panel according to the embodiments of the disclosure;

FIG. 2 is another schematic structural diagram of a liquid crystal display panel according to the embodiments of the disclosure;

FIG. 3 is a schematic structural diagram of a color filter substrate according to the embodiments of the disclosure;

FIG. 4 is a further schematic structural diagram of a liquid crystal display panel according to the embodiments of the disclosure;

FIG. 5 is a schematic flow diagram of fabricating a liquid crystal display panel according to the embodiments of the disclosure;

FIG. 6 is another schematic flow diagram of fabricating a liquid crystal display panel according to the embodiments of the disclosure;

FIG. 7 is a schematic flow diagram of fabricating an organic polymer film on an opposite substrate according to the embodiments of the disclosure;

FIG. 8 is a schematic diagram of performing an atmospheric plasma process on a glass substrate according to the embodiments of the disclosure;

FIG. 9 is a schematic diagram of forming a flexible conductive film on an opposite substrate via a coating process according to the embodiments of the disclosure;

FIG. 10 is a schematic diagram of forming a flexible conductive film on an opposite substrate via an electrostatic atomization process according to the embodiments of the disclosure.

### DETAILED DESCRIPTION OF THE EMBODIMENTS

In order to make the objects, technical solutions, and advantages of the embodiments of the disclosure more apparent, the technical solutions according to the embodiments of the disclosure will be described below clearly and fully with reference to the drawings in the embodiments of the disclosure, and apparently the embodiments described below are only a part but not all of the embodiments of the disclosure. Based upon the embodiments here of the disclosure, all the other embodiments which can occur to those skilled in the art without any inventive effort shall fall into the scope of the disclosure.

Unless otherwise defined, the technical terms or scientific terms as used in the disclosure should be the general meanings understood by those ordinary skilled in the art to which the disclosure belongs. The “first”, “second” and similar words as used in the disclosure do not represent any order, number or importance, but are only used to distinguish the different constituent parts. The “include” or “contain” or similar word means that the element or object appearing before this word encompasses the elements or objects and their equivalents recited after this word, but not exclude other elements or objects. The “connect” or “connect with” or similar word is not limited to the physical or mechanical connection, and can include the electrical connection, regardless of whether it is direct or indirect. The “up”, “down”, “left”, “right” or the like is only used to represent the relative position relationship, and when the absolute position of the described object changes, the relative position relationship may also change accordingly.

In order to keep the following description of the embodiments of the disclosure clear and simple, the detailed description of the known functions and known means is omitted in the disclosure.

As illustrated in FIG. 1, the embodiments of the disclosure provide a liquid crystal display panel, which includes an array substrate 1 and an opposite substrate 2 arranged opposed to the array substrate 1, where a transparent flexible conductive film 3 is arranged on a side of the opposite substrate 2 facing away from the array substrate 1.

In the liquid crystal display panel according to the embodiments of the disclosure, since the transparent flexible conductive film has a better bending property, it can bend together with the opposite substrate when the opposite substrate bends and maintain a good electrical conductivity, and thus can improve the problem that the electrostatic shielding performance of the curved liquid crystal display panel is relatively poor.

In some embodiments, a liquid crystal layer 4 is arranged between the array substrate 1 and the opposite substrate 2.

In some embodiments, the liquid crystal display panel has a structure including the array substrate 1 and a color filter substrate, where the opposite substrate 2 is the color filter substrate; or the liquid crystal display panel has a Color Filter On Array (COA) structure integrating a color filter layer on a side of the array substrate 1, which will be illustrated by following examples respectively.

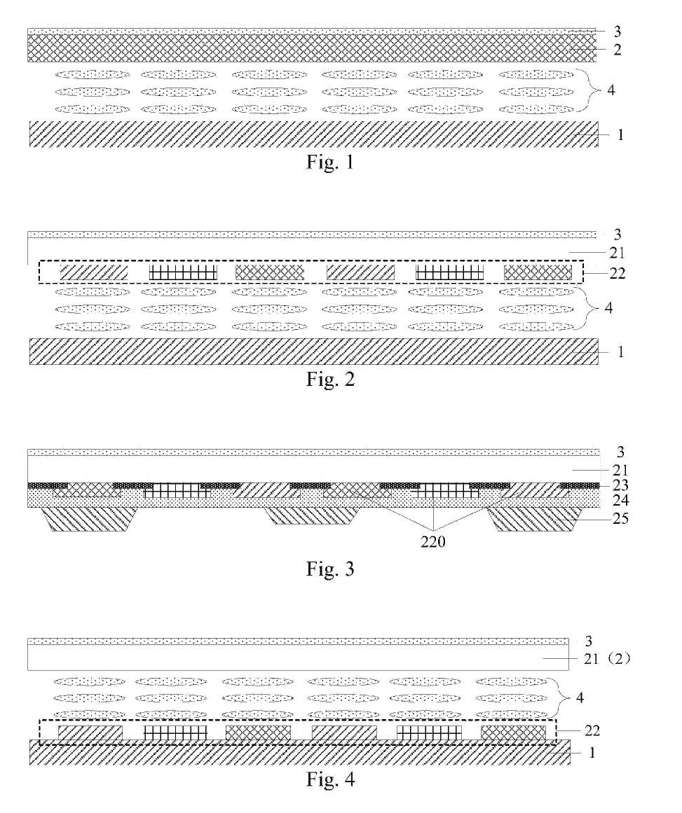

As illustrated in FIG. 2, the opposite substrate is a color filter substrate, and a color filter layer 22 is further arranged on a side of the color filter substrate facing the array substrate 1. That is, the liquid crystal display panel includes the array substrate 1 and the color filter substrate arranged opposed to the array substrate 1, where the color filter substrate includes a base substrate 21 and the color filter layer 22 arranged on a side of the base substrate 21 facing the array substrate 1; and the transparent flexible conductive film 3 is arranged on a side of the base substrate 21 facing away from the array substrate 1. For the color filter substrate, as illustrated in FIG. 2 and FIG. 3, the color filter layer 22 includes a plurality of color resistance elements arranged in an array, where each color resistance element includes three color resistance sub-elements 220 of red, green and blue, and a black matrix 23 is arranged in a gap between adjacent color resistance sub-elements 220; a planarization layer 24 is further arranged on a side of the color filter layer 22 facing away from the base substrate 21, and a post spacer 25 is further arranged on a side of the planarization layer 24 facing away from the color filter layer 22.

As illustrated in FIG. 4, the liquid crystal display panel has the COA structure. The liquid crystal display panel includes the array substrate 1 and the opposite substrate 2 arranged opposed to the array substrate 1, and the opposite substrate 2 includes a base substrate 21, where the liquid crystal display panel further includes a color filter layer 22 arranged on the array substrate 1 (for example, arranged on a side of the array substrate 1 facing the opposite substrate 2), and the transparent flexible conductive film 3 is arranged on a side of the opposite substrate 2 facing away from the array substrate 1.

In some embodiments, the transparent flexible conductive film 3 is an organic polymer conductive film. For example, the transparent flexible conductive film 3 is an organic polymer conductive film made of Poly (3, 4-ethylene dioxythiophene): Poly (styrene sulfonate), (PEDOT: PSS), doped polyaniline or polypyrrole, etc.

In some embodiments, a thickness of the transparent flexible conductive film 3 is 10˜100 nm. When the thickness of the transparent flexible conductive film is 10˜100 nm, it is possible to realize an electrostatic shielding while ensuring that a light transmittance of the transparent flexible conductive film 3 exceeds 90%, which does not affect a normal display of the liquid crystal display panel.

In some embodiments, as illustrated in FIG. 2 to FIG. 4, the opposite substrate 2 includes the base substrate 21, and the organic polymer conductive film is arranged on the side of the base substrate 21 facing away from the array substrate 1, wherein the base substrate 21 is an organic flexible base substrate. Of course, the base substrate 21 can alternatively be a glass base substrate. In the embodiments of the disclosure, the transparent flexible conductive film 3 is arranged on the side of the opposite substrate 2 facing away from the array substrate 1, since the temperature of fabricating the transparent flexible conductive film 3 is lower, the organic flexible base substrate can be selected for the base substrate 21 of the opposite substrate 2, which facilitates the realization of the bending of the liquid crystal display panel.

In some embodiments, the liquid crystal display panel is a curved liquid crystal display panel.

Based upon a same inventive concept, the embodiments of the disclosure further provide a display device including the liquid crystal display panel according to any one of the embodiments of the disclosure. Since the display device addresses the problem under a similar principle to the liquid crystal display panel, reference can be made to the implementation of the liquid crystal display panel for an implementation of the display device, so a repeated description thereof will be omitted here.

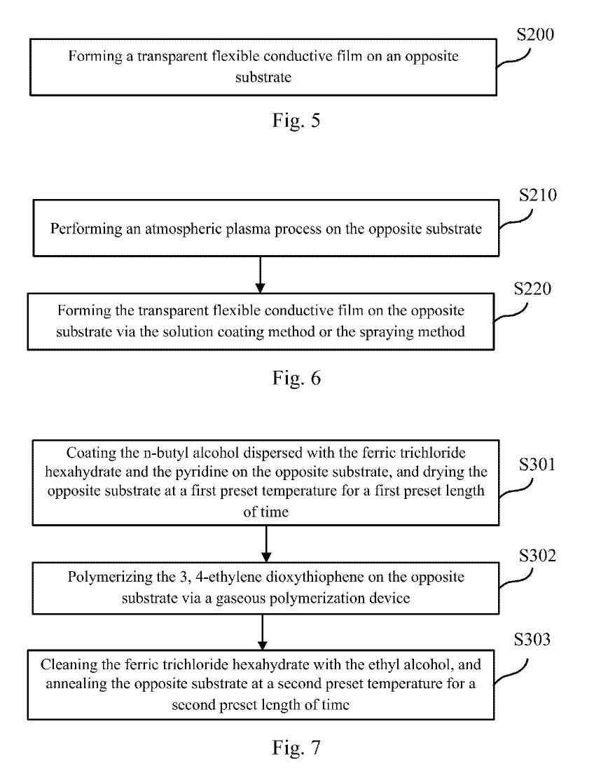

Based upon a same inventive concept, as illustrated in FIG. 5, the embodiments of the disclosure further provide a method for fabricating a liquid crystal display panel, which includes an operation S200 of forming a transparent flexible conductive film on an opposite substrate.

In some embodiments, when box-aligning the opposite substrate with an array substrate, a side of the opposite substrate arranged with the transparent flexible conductive film faces the array substrate.

In some embodiments, the transparent flexible conductive film is formed on the opposite substrate via a solution method or a gas phase method. Where the solution method includes a solution coating method or a spraying method; the gas phase method includes a gaseous polymerization method. That is, forming the transparent flexible conductive film on the opposite substrate includes: forming the transparent flexible conductive film on the opposite substrate via the solution coating method or the spraying method; or forming the transparent flexible conductive film on the opposite substrate via the gaseous polymerization method.

In the embodiments of the disclosure, compared with forming an inorganic film on the opposite substrate via magnetron sputtering, the formation of the transparent flexible conductive film on the opposite substrate via the solution method does not need the expensive sputtering equipment and the fabrication cost is lower. For example, if the solution coating method is used, the coating device of the factory of fabricating the color filter substrate can be employed in the fabrication process to achieve a low-cost fabrication. And for the formation of the transparent flexible conductive film on the opposite substrate via the gaseous polymerization method, the thickness and the electrical conductivity of the transparent flexible conductive film can be controlled precisely and the cost is also lower.

In some embodiments, forming the transparent flexible conductive film on the opposite substrate via the spraying method includes: coating micro-droplets on the opposite substrate via an ultrasonic method or an electrostatic atomization method, and drying the opposite substrate.

In some embodiments, as illustrated in FIG. 6, before an operation S220 of forming the transparent flexible conductive film on the opposite substrate via the solution coating method or the spraying method, the method further includes an operation S210 of performing an atmospheric plasma process on the opposite substrate. For example, performing an atmospheric plasma process on a side of the opposite substrate at which the transparent flexible conductive film is to be formed.

In some embodiments, the opposite substrate includes a glass base substrate, i.e. the transparent flexible conductive film is arranged on the glass base substrate, where the transparent flexible conductive film is an organic polymer conductive film, e.g., an organic polymer conductive film made of PEDOT: PSS, doped polyaniline or polypyrrole, etc. In the embodiments of the disclosure, the atmospheric plasma process is performed on the opposite substrate, which can increase the hydrophilia of the surface of the opposite substrate and improve the adhesive strength of the surface of the opposite substrate for the transparent flexible conductive film.

In some embodiments, forming the transparent flexible conductive film on the opposite substrate via the gaseous polymerization method includes: forming the poly (3, 4-ethylene dioxythiophene): poly (styrene sulfonate) film on the opposite substrate via the gaseous polymerization method.

In some embodiments, forming the poly (3, 4-ethylene dioxythiophene): poly (styrene sulfonate) on the opposite substrate via the gaseous polymerization method, as illustrated in FIG. 7, includes following operations.

Operation S301: coating the n-butyl alcohol dispersed with the ferric trichloride hexahydrate and the pyridine on the opposite substrate, and drying the opposite substrate at a first preset temperature for a first preset length of time, wherein the ferric trichloride hexahydrate is used as an oxidizing agent and the pyridine is used as an inhibitor.

Operation S302: polymerizing the 3, 4-ethylene dioxythiophene on the opposite substrate via a gaseous polymerization device.

Operation S303: cleaning the ferric trichloride hexahydrate with the ethyl alcohol, and annealing the opposite substrate at a second preset temperature for a second preset length of time.

Where the first preset temperature, the second preset temperature, the first preset length of time and the second preset length of time can be set as needed in reality. It shall be noted that, it is suitable for the first preset temperature and the second preset temperature to be not greater than 100 degrees Celsius in order to avoid the effect of the temperature on the organic polymer conductive film.

In order to understand the method for fabricating the liquid crystal display panel according to the embodiments of the disclosure more clearly, the formation of the transparent flexible conductive film on the color filter substrate will be illustrated below in details by taking the case that the liquid crystal display panel includes the array substrate and the color filter substrate arranged opposed to the array substrate as an example.

In some embodiments, forming the transparent flexible conductive film on the color filter substrate includes following operations.

Operation 211: cleaning a glass substrate, where the glass substrate is a base substrate of the color filter substrate.

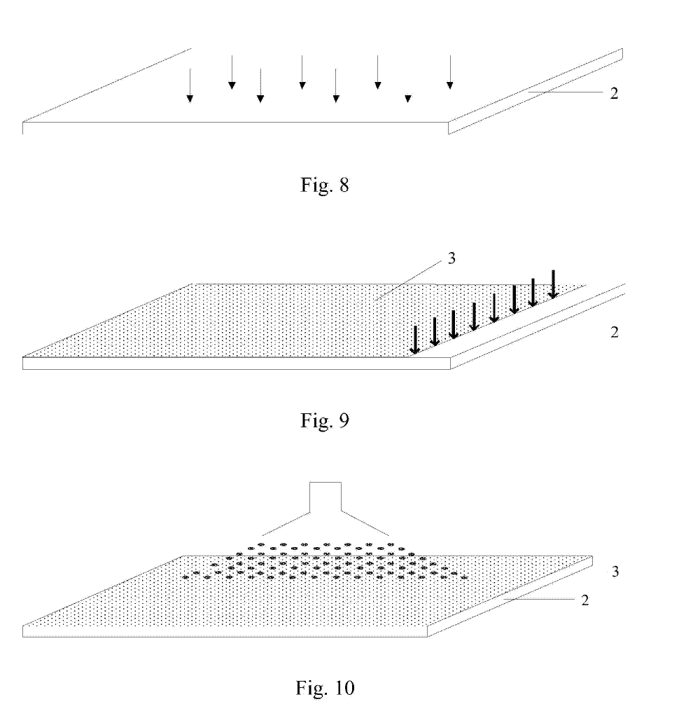

Operation 212: performing an Atmospheric Plasma (AP Plasma) process on a surface of the glass substrate as illustrated in FIG. 8, so as to increase the hydrophilia of the glass base substrate; where the arrows in FIG. 8 illustrate the processing of the plasmas on the surface of the glass substrate.

Operation 213: mixing the PEDOT dilute solution with a doped material; where the doped material can be a solvent with a strong polarity and high boiling point of ethylene glycol, glycerol or dimethyl sulfoxide (DMSO), where the solvent with the strong polarity and high boiling point can enhance the electrical conductivity of the PEDOT: PSS film formed later.

Operation 214: coating the above mixed solution on the surface of the glass substrate, on which the AP Plasma process is performed, by using the coating device, and drying the glass substrate, as illustrated in FIG. 9; where the black arrows in FIG. 9 represent the nozzles of the coating device.

In some embodiments, forming the transparent flexible conductive film on the color filter substrate includes following operations.

Operation 221: cleaning a glass substrate, where the glass substrate is a base substrate of the color filter substrate.

Operation 222: performing an Atmospheric Plasma (AP Plasma) process on a surface of the glass substrate, as illustrated in FIG. 8, so as to increase the hydrophilia of the glass base substrate.

Operation 223: mixing the PEDOT dilute solution with a doped material; where the doped material can be a solvent with a strong polarity and high boiling point of ethylene glycol, glycerol or dimethyl sulfoxide (DMSO), where the solvent with the strong polarity and high boiling point can enhance the electrical conductivity of the PEDOT: PSS film formed later.

Operation 224: coating micro-droplets of the above mixed solution on the surface of the glass substrate, on which the AP Plasma process is performed, by using the ultrasonic or electrostatic atomization method, as illustrated in FIG. 10, and drying the glass substrate.

In some embodiments, forming the transparent flexible conductive film on the color filter substrate includes following operations.

Operation 231: coating the n-butyl alcohol dispersed with the ferric trichloride hexahydrate and the pyridine on a surface of a glass substrate, and drying the glass substrate at 70□ for 30 minutes to remove the n-butyl alcohol, where the ferric trichloride hexahydrate is used as an oxidizing agent, the pyridine is used as an inhibitor, and the glass substrate is a base substrate of the color filter substrate.

Operation 232: polymerizing the 3, 4-ethylene dioxythiophene (EDOT) on the surface of the glass substrate via a gaseous polymerization device.

Operation 233: cleaning the glass substrate with the ethyl alcohol to remove the redundant ferric trichloride hexahydrate, and annealing the glass substrate at 60□ for 30 minutes.

The advantageous effects of the embodiments of the disclosure are as follows: the liquid crystal display panel according to the embodiments of the disclosure includes the array substrate and the opposite substrate arranged opposed to the array substrate, where the transparent flexible conductive film is arranged on a side of the opposite substrate facing away from the array substrate. Since the transparent flexible conductive film has a better bending property, it can bend together with the opposite substrate when the opposite substrate bends and maintain a good electrical conductivity, and thus can address the problem that the electrostatic shielding performance of the curved liquid crystal display panel is relatively poor. Also, the fabrication of the transparent flexible conductive film on the side of the opposite substrate facing away from the array substrate does not need the expensive fabrication equipment and can reduce the fabrication cost of the liquid crystal display panel effectively, and the transparent flexible conductive film is different from the granular inorganic film and does not have the problem of difficult management and control of the granular inorganic film which affects the subsequent fabrication procedures.

Evidently those skilled in the art can make various modifications and variations to the disclosure without departing from the spirit and scope of the disclosure. Thus the disclosure is also intended to encompass these modifications and variations therein as long as these modifications and variations come into the scope of the claims of the disclosure and their equivalents.

What is claimed is:

1. A liquid crystal display panel, comprising: an array substrate and an opposite substrate arranged opposed to the array substrate, wherein a transparent flexible conductive film is arranged on a side of the opposite substrate facing away from the array substrate.

2. The liquid crystal display panel according to claim 1, wherein the transparent flexible conductive film is an organic polymer conductive film.

3. The liquid crystal display panel according to claim 2, wherein the opposite substrate comprises an organic flexible base substrate, the organic polymer conductive film is arranged on a side of the organic flexible base substrate facing away from the array substrate.

4. The liquid crystal display panel according to claim 2, wherein a material of the organic polymer conductive film is poly (3, 4-ethylene dioxythiophene): poly (styrene sulfonate), doped polyaniline or polypyrrole.

5. The liquid crystal display panel according to claim 1, wherein a thickness of the transparent flexible conductive film is 10˜100 nm.

6. The liquid crystal display panel according to claim 1, wherein the opposite substrate is a color filter substrate and a color filter layer is arranged on a side of the color filter substrate facing the array substrate.

7. The liquid crystal display panel according to claim 1, wherein the liquid crystal display panel further comprises a color filter layer and the color filter layer is arranged on the array substrate.

8. The liquid crystal display panel according to claim 1, wherein the liquid crystal display panel is a curved liquid crystal display panel.

9. A display device, comprising a liquid crystal display panel, wherein the liquid crystal display panel comprises an array substrate and an opposite substrate arranged opposed to the array substrate, wherein a transparent flexible conductive film is arranged on a side of the opposite substrate facing away from the array substrate.

10. The display device according to claim 9, wherein the transparent flexible conductive film is an organic polymer conductive film.

11. The display device according to claim 10, wherein the opposite substrate comprises an organic flexible base substrate, the organic polymer conductive film is arranged on a side of the organic flexible base substrate facing away from the array substrate.

12. The display device according to claim 10, wherein a material of the organic polymer conductive film is poly (3, 4-ethylene dioxythiophene): poly (styrene sulfonate), doped polyaniline or polypyrrole.

13. The display device according to claim 9, wherein a thickness of the transparent flexible conductive film is 10˜100 nm.

14. A method for fabricating a liquid crystal display panel, comprising: forming a transparent flexible conductive film on an opposite substrate.

15. The method for fabricating the liquid crystal display panel according to claim 14, wherein forming the transparent flexible conductive film on the opposite substrate comprises:
forming the transparent flexible conductive film on the opposite substrate via a solution coating method or a spraying method.

16. The method for fabricating the liquid crystal display panel according to claim 15, wherein forming the transparent flexible conductive film on the opposite substrate via the spraying method, comprises:
coating micro-droplets on the opposite substrate via an ultrasonic method or an electrostatic atomization method, and drying the opposite substrate.

17. The method for fabricating the liquid crystal display panel according to claim 15, wherein before forming the transparent flexible conductive film on the opposite substrate via the solution coating method or the spraying method, the method further comprises:
performing an atmospheric plasma process on the opposite substrate.

18. The method for fabricating the liquid crystal display panel according to claim 14, wherein forming the transparent flexible conductive film on the opposite substrate, comprises:
forming the transparent flexible conductive film on the opposite substrate via a gaseous polymerization method.

19. The method for fabricating the liquid crystal display panel according to claim 18, wherein forming the transparent flexible conductive film on the opposite substrate via the gaseous polymerization method, comprises:
forming a poly (3, 4-ethylene dioxythiophene): poly (styrene sulfonate) film on the opposite substrate via the gaseous polymerization method.

20. The method for fabricating the liquid crystal display panel according to claim 19, wherein forming the poly (3, 4-ethylene dioxythiophene): poly (styrene sulfonate) film on the opposite substrate via the gaseous polymerization method, comprises:
coating an n-butyl alcohol dispersed with a ferric trichloride hexahydrate and a pyridine on the opposite substrate, and drying the opposite substrate at a first preset temperature for a first preset length of time;
polymerizing a 3,4-ethylene dioxythiophene on the opposite substrate via a gaseous polymerization device;
cleaning the opposite substrate with an ethyl alcohol, and annealing the opposite substrate at a second preset temperature for a second preset length of time.
